(19) United States
(12) Patent Application Publication
(10) Pub. No.: US 2018/0315857 A1
(43) Pub. Date: Nov. 1, 2018

(54) DEVICE AND METHOD TO IMPROVE FIN TOP CORNER ROUNDING FOR FINFET

(71) Applicants: Semiconductor Manufacturing International (Shanghai) Corporation, Shanghai (CN); Semiconductor Manufacturing International (Beijing) Corporation, Beijing (CN)

(72) Inventor: Yong Li, Shanghai (CN)

(21) Appl. No.: 15/918,693

(22) Filed: Mar. 12, 2018

(30) Foreign Application Priority Data
Apr. 28, 2017 (CN) 201710290101.0

(51) Int. Cl. H01L 29/78; H01L 29/66; H01L 21/311; H01L 21/3105; H01L 21/324; H01L 21/8234; H01L 27/088; H01L 29/10; H01L 29/423

(52) U.S. Cl. CPC H01L 29/7854; H01L 29/66818; H01L 29/66545; H01L 21/31111; H01L 21/3105; H01L 21/3247; H01L 29/42364; H01L 21/823412; H01L 21/823437; H01L 21/823462; H01L 27/0886; H01L 29/1037; H01L 21/823431

(57) ABSTRACT

A method for manufacturing a semiconductor device includes providing a substrate structure including a substrate, a plurality of fins on the substrate, a hardmask layer on the fins, and a first insulating layer on the substrate for isolating the fins. The first insulating layer has an upper surface substantially flush with an upper surface of the hardmask layer. The method also includes etching back the first insulating layer to form a second insulating layer having an upper surface lower than a bottom surface of the hardmask layer, performing an oxidation process or an annealing process on the second insulating layer, removing the hardmask layer after performing the oxidation process or the annealing process, and etching back the second insulating layer to form an insulating region having an upper surface lower than an upper surface of the fins.

### CROSS-REFERENCES TO RELATED APPLICATIONS

The present application claims priority to Chinese patent application No. 201710290101.0, filed with the State Intellectual Property Office of People's Republic of China on Apr. 28, 2017, the content of which is incorporated herein by reference in its entirety.

### FIELD OF THE INVENTION

The present application relates to integrated semiconductor devices, and more particularly to a FinFET transistor having rounder corners and method for manufacturing the same.

### BACKGROUND OF THE INVENTION

As the critical dimension of metal oxide semiconductor field effect transistor (MOSFET) devices continues to shrink, the short channel effect becomes more problematic. Fin field effect transistor (FinFET) devices have better control capability of gates than planar MOSFET devices to effectively suppress the short channel effect.

The inventor of the present application has found that rounding fin corners can improve FinFET performance. If the process of corner rounding is poor, many problems may be present such as humps in the current-voltage (IV) curve, reverse short channel effects, gate induced leakage current, and poor reliability of the FinFET device.

Conventional FinFET manufacturing processes cannot provide the roundness of the corners of the top of the fins. Therefore, there is a need for a novel for manufacturing method to round top corners of a semiconductor fin of a finFET device.

### BRIEF SUMMARY OF THE INVENTION

Embodiments of the present disclosure provide a novel method of manufacturing a semiconductor device that can realize rounded top surface corners and edges of the fin top.

In one aspect of the present disclosure, a method for manufacturing a semiconductor device may include providing a substrate structure including a substrate, a plurality of fins on the substrate, a hardmask layer on the fins, and a first insulating layer on the substrate for isolating the fins. The first insulating layer has an upper surface substantially flush with an upper surface of the hardmask layer. The method may further include etching back the first insulating layer to form a second insulating layer having an upper surface lower than a bottom surface of the hardmask layer, performing an oxidation process or an annealing process on the second insulating layer, removing the hardmask layer after performing the oxidation process or the annealing process and etching back the second insulating layer to form an insulating region having an upper surface lower than an upper surface of the fins.

In one embodiment, a distance between the upper surface of the second insulating layer and the bottom surface of the hardmask layer is in a range between 3 nm and 15 nm.

In one embodiment, the oxidation process may include a dry oxidation process, a wet oxidation process, or an in-situ steam generation process.

In one embodiment, the annealing process is performed in an annealing environment including hydrogen or helium, at a temperature in a range between 600° C. and 800° C., at a pressure in a range between 10 Torr and 1 atmosphere, and for a time period in a range between 10 minutes and 240 minutes.

In one embodiment, the plurality of fins include a first fin for a first device and a second fin for a second device.

In one embodiment, the method further includes forming a first gate structure on the first fin and a second gate structure on the second fin,. The first gate structure includes a gate dielectric layer on an exposed surface of the first fin, a first high-k dielectric layer on the gate dielectric layer, and a first gate on the first high-k dielectric layer. The second gate structure includes an interface layer on an exposed surface of the second fin, a second high-k dielectric layer on the interface layer, and a second gate on the second high-k dielectric layer.

In one embodiment, forming the first gate structure on the first fin and the second gate structure on the second fin includes forming a first dummy gate dielectric layer on the exposed surface of the first fin, forming a second dummy gate dielectric layer on the exposed surface of the second fin, the first dummy gate dielectric layer having a thickness greater than a thickness of the second dummy gate dielectric layer, forming dummy gates on the first dummy gate dielectric layer and on the second dummy gate dielectric layer, forming an interlayer dielectric layer on the dummy gates, planarizing the interlayer dielectric layer to expose a surface of the dummy gate, removing the dummy gate, and removing the second dummy gate dielectric layer. The method further includes forming the interface layer on the exposed surface of the second fin, forming a high-k dielectric layer on the interface layer and on the first dummy gate dielectric layer, the first dummy gate dielectric layer being a gate dielectric layer, a portion of the high-k dielectric layer on the first dummy gate dielectric layer being a first high-k dielectric layer, and a portion of the high-k dielectric layer on the interface layer being a second high-k dielectric layer. The method also includes forming the first gate on the portion of the high-k dielectric layer on the first dummy gate dielectric layer and the second gate on the portion of the high-k dielectric layer on the interface layer.

In one embodiment, the first device comprises an input/output device, and the second device comprises a core device.

In another aspect of the present disclosure, a semiconductor device includes a substrate, a plurality of fins on the substrate and having rounded corners and edges on an upper portion of the fins, a hardmask layer on the fins, and an insulating region on the substrate for isolating the fins and having an upper surface higher than a bottom surface of the hardmask layer.

In one embodiment, a distance between the upper surface of the insulating region and a bottom surface of the hardmask layer is in a range between 3 nm and 15 nm.

In yet another aspect of the present disclosure, a second semiconductor device may include a substrate, a plurality of fins on the substrate and having rounded corners and edges on an upper portion of the fins, a hardmask layer on the fins, and an insulating region on the substrate for isolating the fins and having an upper surface lower than an upper surface of the fins.

In one embodiment, the plurality of fins include a first fin for a first device and a second fin for a second device.

In one embodiment, the second semiconductor device further includes a first gate structure on the first fin comprising: a gate dielectric layer on an exposed surface of the first fin, a first high-k dielectric layer on the gate dielectric layer, and a first gate on the first high-k dielectric layer. In one embodiment, the second semiconductor device also includes a second gate structure on the first fin comprising: an interface layer on an exposed surface of the second fin, a second high-k dielectric layer on the interface layer, and a second gate on the second high-k dielectric layer.

In one embodiment, the first device includes an input/output device, and the second device includes a core device

The following detailed description together with the accompanying drawings will provide a better understanding of the nature and advantages of the present invention.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 is a simplified flowchart of a method for manufacturing a semiconductor device according to some embodiments of the present disclosure.

FIGS. 2A to 2E are cross-sectional views of intermediate stages of a manufacturing method of a semiconductor device according to an embodiment of the present disclosure.

FIGS. 3A to 3I are cross-sectional views of intermediate stages of a manufacturing method of a semiconductor device according to another embodiment of the present disclosure.

### DETAILED DESCRIPTION OF THE INVENTION

Embodiments of the present disclosure now will be described more fully hereinafter with reference to the accompanying drawings. The disclosure may, however, be embodied in many different forms and should not be construed as limited to the embodiments set forth herein. Rather, these embodiments are provided so that this disclosure will be thorough and complete, and will fully convey the scope of the invention to those skilled in the art. The features may not be drawn to scale, some details may be exaggerated relative to other elements for clarity. bike numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present

Relative terms such as “below” or “above” or “upper” or “lower” or “horizontal” or “lateral” or “vertical” may be used herein to describe a relationship of one element, layer or region to another element, layer or region as illustrated in the figures. It will be understood these terms are intended to encompass different orientations of the device in addition to the orientation depicted in the figures.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises”, “comprising”, “includes”, and/or “including” when used herein, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to cross-sectional illustrations that are schematic illustrations of idealized embodiments (and intermediate structures) of the invention. The thickness of layers and regions in the drawings may be enlarged relative to other layers and regions for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Embodiments of the present disclosure now will be described more fully hereinafter with reference to the accompanying drawings, in which embodiments of the invention are shown. This disclosure may, however, be embodied in many different forms and should not be construed as limited to the embodiments set forth herein.

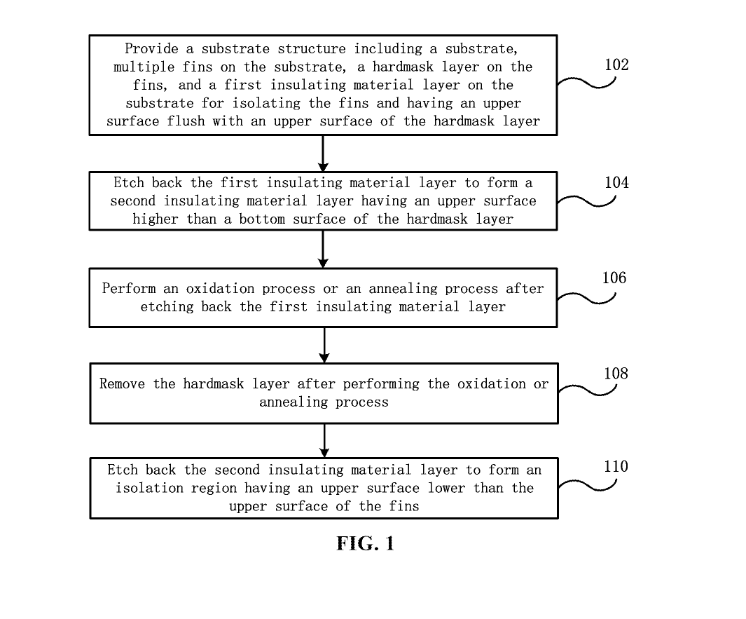

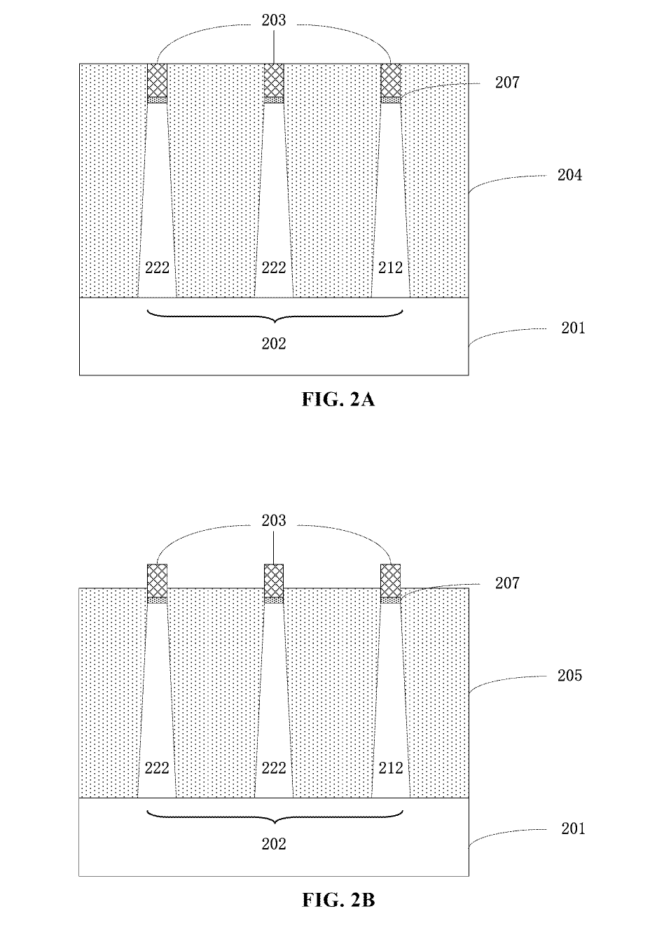

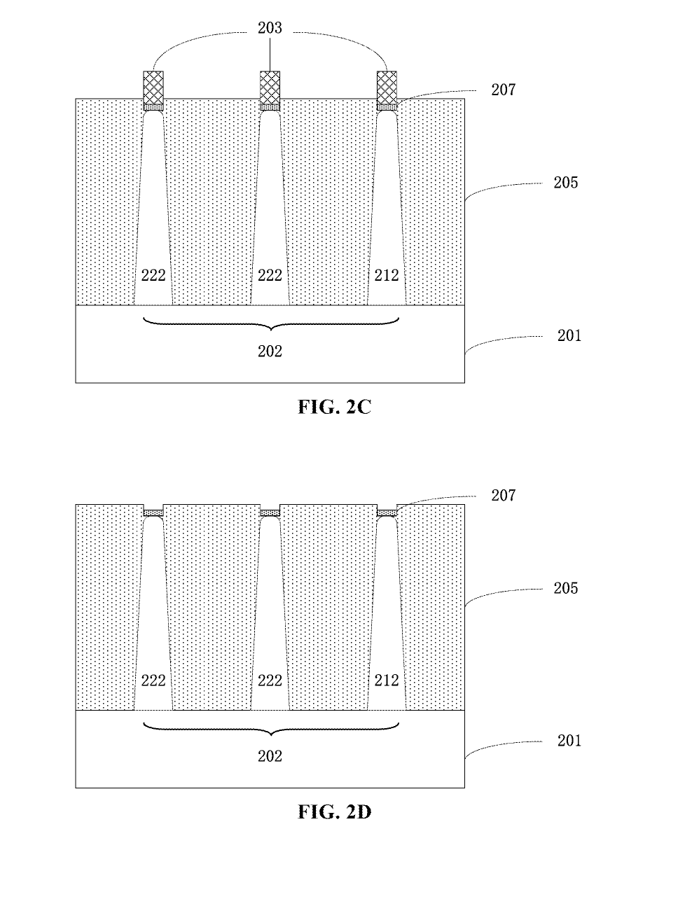

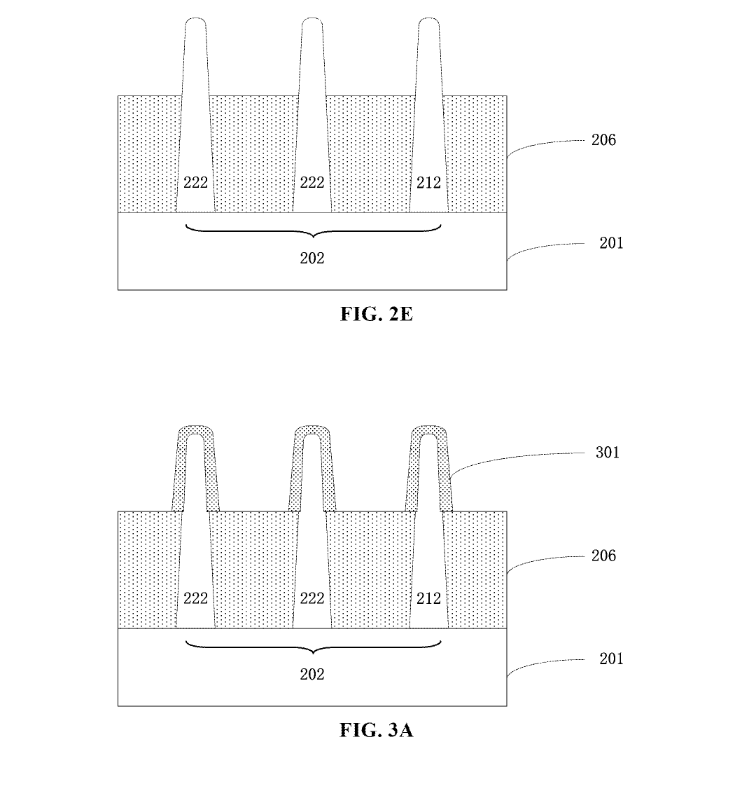

FIG. 1 is a simplified flowchart of a method for manufacturing a semiconductor device according to some embodiments of the present disclosure. FIGS. 2A to 2E are cross-sectional views of intermediate stages of a manufacturing method of a semiconductor device according to an embodiment of the present disclosure.

A method of manufacturing a semiconductor device according to an embodiment of the present disclosure will be described in detail with reference to FIG. 1 and FIGS. 2A to 2E.

Referring to FIG. 1, the method includes, at block 102, providing a substrate structure. Referring to FIG. 2A, the substrate structure include a substrate 201, a plurality of semiconductor fins 202 on substrate 201, a hardmask layer 203 on the upper surface of fins 202, and a first insulating material layer 204 on substrate 201 for isolating fins 202. First insulating material layer 204 has an upper surface that is substantially flush with an upper surface of hardmask layer 203 within the process variations. In one embodiment, a buffer layer (also referred to as pad oxide layer) 207 may be disposed between fins 202 and hardmask layer 203 for increasing the adhesive strength between fins 202 and hardmask layer 203. As used herein, the term “substantially flush” refers to arrangements where the surfaces are flush (i.e., coplanar) within the process variation toelerance.

Substrate 201 may be a silicon substrate or a III-V compound semiconductor substrate. Fins 202 may include the same material as the material of substrate 201 or have a material different from that of substrate 201. Hardmask layer 203 may include silicon nitride, silicon oxide, or silicon oxynitride. First insulating material layer 204 may include a dielectric material, e.g., silicon oxide.

In one embodiment, fins 202 may include a first fin 212 for a first device and a second fin 222 for a second device. In one embodiment, the first device is an input/output (I/O) device, and the second device is a core device. It is understood that the number of fins can be any integer number. In the example shown in FIG. 2A and subsequent drawings, one fin 212 is used for the first device, and two fins 222 are used for the second device. But is it understood that the number is arbitrarily chosen for describing the example embodiment and should not be limiting.

In one embodiment, the substrate structure may be formed using the following process steps: first, a patterned hardmask layer 203 is formed on an initial substrate. The initial substrate is then etched using patterned hardmask layer 203 as a mask to form substrate 201 and fins 202. Thereafter, an insulating material is deposited on fins 202 and hardmask layer 203 filling air gaps between the fins. The insulating material may be deposited by a CVD (e.g., flowable chemical vapor deposition) process. Next, the insulating material is planarized, e.g., using a chemical mechanical polishing process, so that the upper surface of the remaining (i.e., polished) insulating material, i.e., first insulating material layer 204, is substantially flush with the upper surface of hardmask layer 203 to form the substrate structure. In one embodiment, a liner layer may also be formed on the surface of fins 202 prior to depositing the insulating material to repair damage to the fins when fins 202 are etched. In one embodiment, an annealing process may also be performed between the processes of deposition and planarization of the insulating material.

Referring back to FIG. 1, the method includes, at block 104, etching back first insulating layer 204 to form a second insulating layer 205 having an upper surface higher than a bottom surface of hardmask layer 203, as shown in FIG. 2B. Herein, second insulating layer 205 is the remaining first insulating layer 204 after the (first) etching back process. In one embodiment, in order to avoid oxygen in the subsequent oxidation process and some elements (e.g., hydrogen) in the environment in the annealing process to excessively enter into fins 202, the distance between the upper surface of second insulating material layer 205 and the bottom surface of hardmask layer 203 must be within the range between 3 nm and 15 nm, e.g., 5 nm, 8 nm, 10 nm, 12 nm, etc.

After etching back first insulating layer 204, the method includes, at block 106, performing an oxidation process or an annealing process. The oxidation process and the annealing process may cause the corners and edges of fins 202 to be rounded, as shown in FIG. 2C.

In one embodiment, the oxidation process may include a dry oxidation process, a wet oxidation process, or an in-situ steam generation (ISSG) process. In the oxidation process, the corners and edges of the top portion of fins 202 are oxidized, so that the corners and edges become rounded.

In one embodiment, the annealing process may be performed in an annealing environment including hydrogen or helium, at a temperature in the range between 600° C. and 800° C. (e.g., 650° C., 700° C.), at a pressure in the range between 1 Torr and 1 atmosphere (e.g., 50 Torr, 100 Torr, 300 Torr), with an annealing time period in the range between 10 minutes and 240 minutes (e.g., 20 minutes, 60 minutes, 120 minutes). In the annealing process, the material at the corners and edges of fins 202 migrates, so that the corners and edges become rounded.

After the oxidation process or the annealing process, the method includes, at block 108, removing hardmask layer 203, as shown in FIG. 2D.

Thereafter, the method includes, at block 110, etching back second insulating material layers 205 to form an insulating region 206 having an upper surface lower than the upper surface of fins 202, as shown in FIG. 2E. Herein, insulating region 206 is a remaining portion of second insulating layer 205 after the (second) etching back process. It is to be noted that, in the case where buffer layer 207 is provided between fins 202 and hardmask layer 203, buffer layer 207 may be removed at the same time when second insulating layer 205 is etched back, or buffer layer 207 may be removed by an additional etching process. In the embodiment, the (second) etching back process of second insulating layer 205 also exposes the surface of fins 202 above an upper surface of insulating region 206.

The above-described embodiments of the present disclosure provide a method for manufacturing a semiconductor device. The method forms an insulating region using two etching back processes, and performs an oxidation process or an annealing process after the first etching back process, so that the corners and the edges of the top portion of the fins are rounded to reduce or eliminate problems of the reverse short channel effect, gate induced leakage current and poor reliability of the semiconductor device. Further, the insulating region will be densified by the oxidation process, and the densification will reduce loss of the insulating region caused by subsequent processes (e.g., a wet etching process).

Thereafter, a first gate structure is formed on first fin 212, and a second gate structure is formed on second fin 222.

An embodiment of forming the first gate structure and the second gate structure will be described in detail below.

In one embodiment, a first dummy gate dielectric layer 301 is formed on the exposed surface (the surface above the upper surface of insulating region 206) of first fin 212, and a second dummy gate dielectric layer 302 is formed on the exposed surface (the surface above the upper surface of insulating region 206) of second fin 222. In the embodiment, first dummy gate dielectric layer 301 has a thickness that is greater than a thickness of second dummy gate dielectric layer 302.

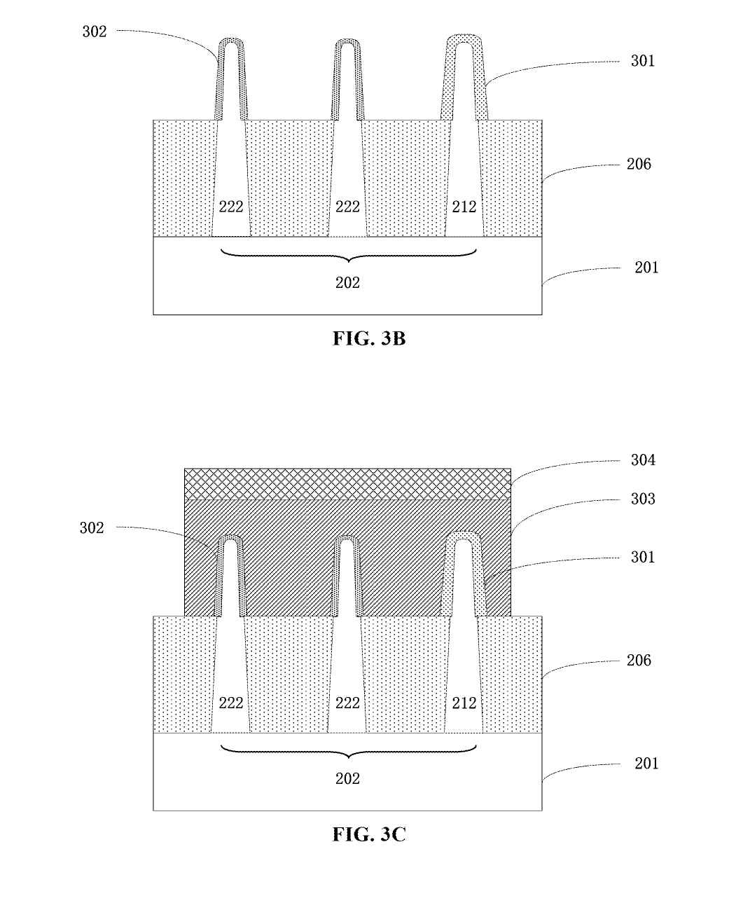

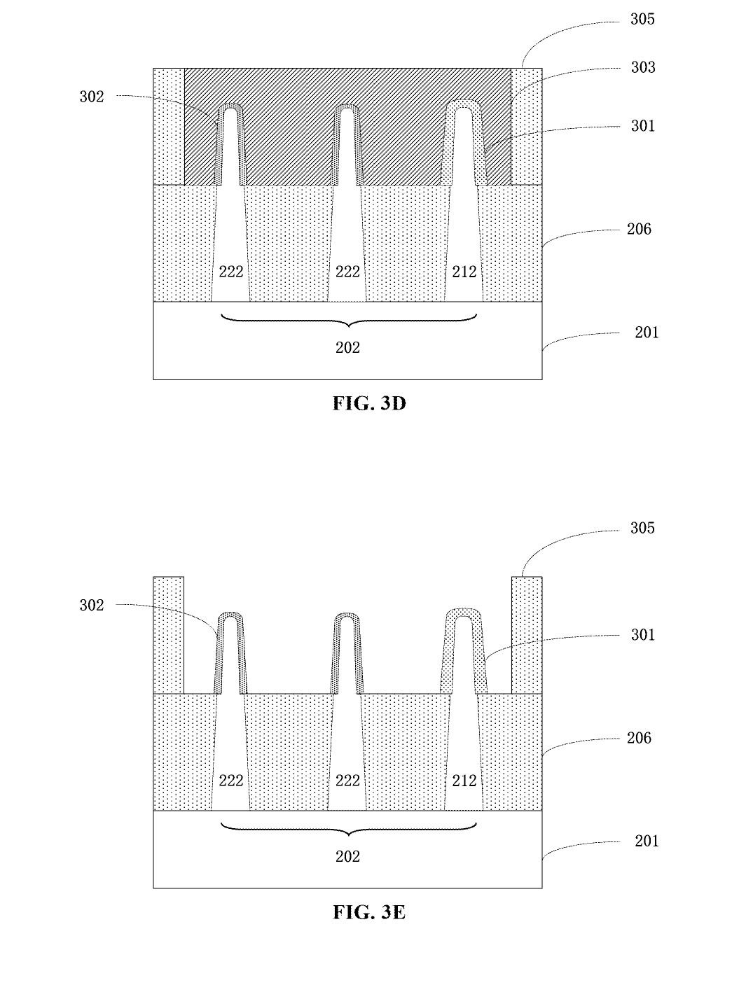

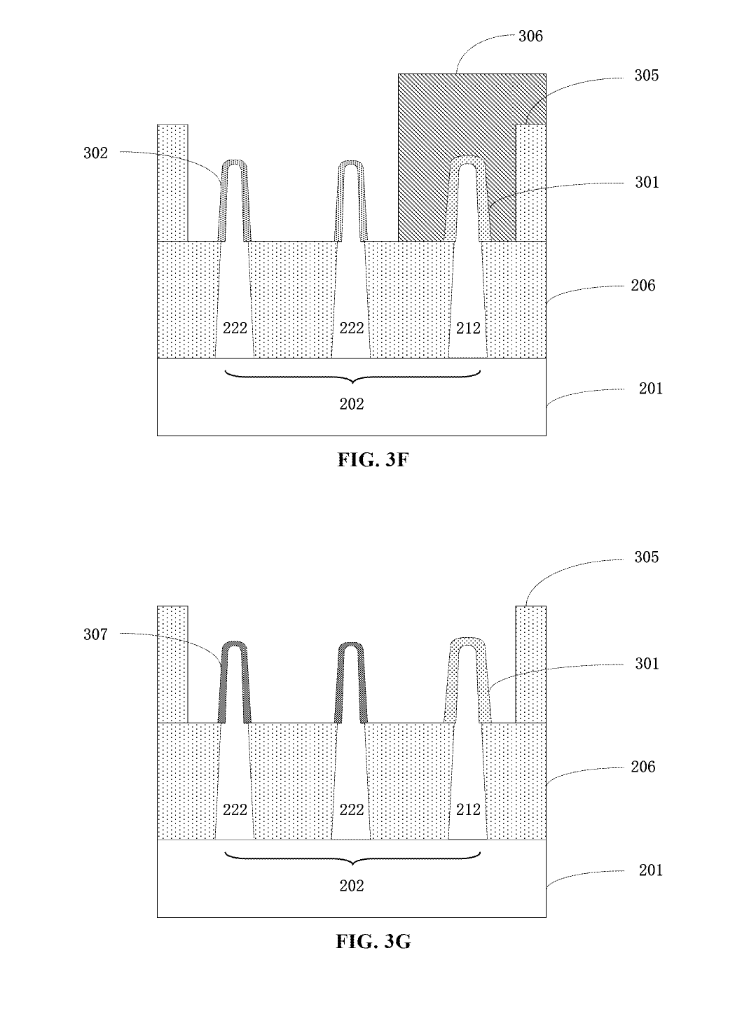

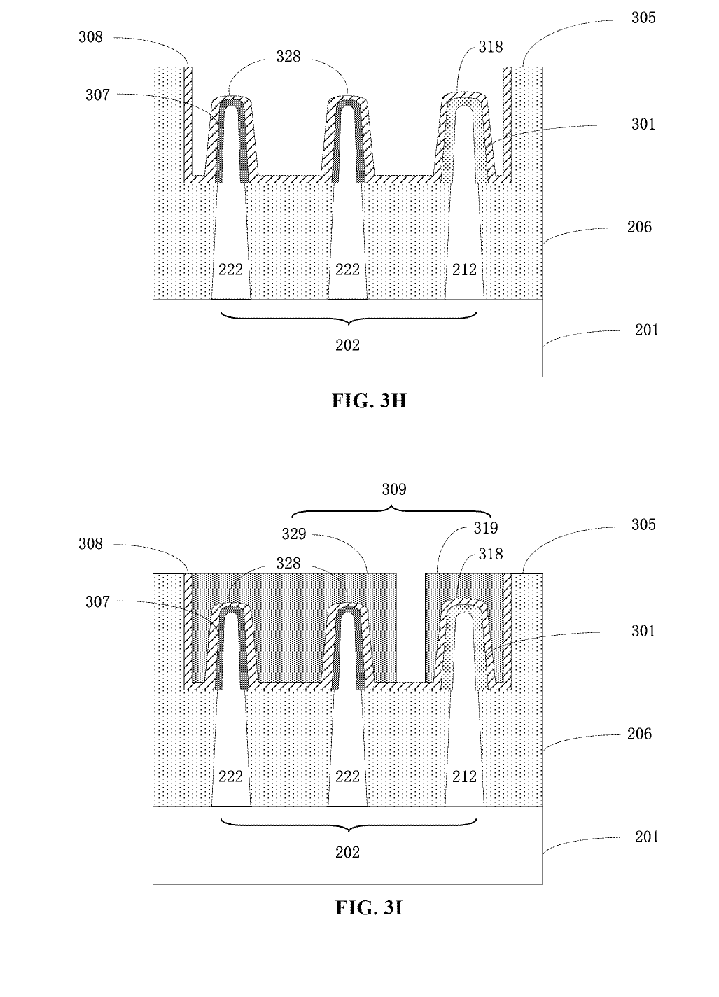

In one exemplary embodiment, forming first dummy gate dielectric layer 301 and second dummy gate dielectric layer 302 will be described with reference to FIGS. 3A and 3B.

Referring to FIG. 3A, a first dummy gate dielectric layer (e.g., a silicon oxide layer) 301 is formed on the exposed surface of first fin 212 and second fin 222 using an in-situ steam generation (ISSG) process.

Referring to FIG. 3B, first dummy gate dielectric layer 301 on second fin 222 is removed to expose a surface of second fin 222 above the upper surface of insulating region 206, and a second dummy gate dielectric layer 302 having a thickness smaller than the thickness of first dummy gate dielectric layer 301 is then formed on the exposed surface of second fin 222. For example, a silicon oxide layer may be formed as second dummy gate dielectric layer 302 on the exposed surface of second fin 222 using an ISSG process.

Next, referring to FIG. 3C, a dummy gate (e.g., a polycrystalline silicon dummy gate) 303 is formed on first dummy gate dielectric layer 301 and second dummy gate dielectric layer 302.

In one embodiment, a dummy gate material may be deposited on the structure shown in FIG. 3B. The dummy gate material is then planarized. A patterned hardmask 304 is formed on the planarized dummy gate material. The dummy gate material is then patterned using hardmask 304 as a mask to form dummy gate 303. Thereafter, hardmask 304 is removed.

Next, referring to FIG. 3D, an interlayer dielectric layer (e.g., a silicon oxide layer) 305 is deposited on the structure shown in FIG. 3C. A planarization process is performed on interlayer dielectric layer 305 to expose dummy gate 303.

Next, referring to FIG. 3E, dummy gate 303 is removed to form a trench.

Thereafter, referring to FIG. 3F, second dummy gate dielectric layer 302 is removed to expose a surface of second fin 222 above the upper surface of insulating region 206.

In one exemplary embodiment, a patterned mask layer 306 may be formed in the trench to cover first dummy gate dielectric layer 301 while exposing second dummy gate dielectric layer 302. Second dummy gate dielectric layer 302 is then removed using a dry or wet etching process to expose a surface of second fin 222. Thereafter, patterned mask layer 306 is removed.

It should be noted that, in one embodiment, removing second dummy gate dielectric layer 202 may also remove a portion of insulating region 206 that is not covered by mask layer 306, resulting in a loss of the insulating region, so that a portion of insulating region 206 covered by mask layer 306 has a height that is different from a height of a portion of insulating region 206 not covered by mask layer 306. As described above, by performing the oxidation process, insulating region 208 is densified, so that the loss of insulating region 206 can be reduced.

Next, referring to FIG. 3G, an interface layer 307 is formed on the exposed surface of second fin 222. In one example embodiment, a silicon oxide layer may be formed by thermal growth as interface layer 307. In one embodiment, a pre-cleaning process may be performed on second fin 222 prior to forming interface layer 307 to remove any residues left in the removal of second dummy gate dielectric layer 302.

Next, referring to FIG. 3H, a high-k dielectric layer (e.g., hafnium oxide) 308 is formed on interface layer 307 and first dummy gate dielectric layer 301. In one embodiment, high-k dielectric layer 308 may also be formed on sidewalls of the trench and on the surface of insulating region 206. First dummy gate dielectric layer 301 operates as a gate dielectric layer for the first device. A portion of high-k dielectric layer 308 on first dummy gate dielectric layer 301 operates as first high-k dielectric layer 318, and a portion of high-k dielectric layer 308 on interface layer 307 operates as second high-k dielectric layer 328.

Further, the method also includes performing an annealing process after forming high-k dielectric layer 308.

Next, referring to FIG. 31, a first gate 319 is formed on first high-k dielectric layer 318, and a second gate 329 is formed on second high-k dielectric layer 328.

In on embodiment, a gate material (e.g., a metal) 309 is deposited on high-k dielectric layer 308. Gate material 309 is then patterned to form first gate 319 and second gate 329.

The processes of forming the first gate structure and the second gate structure have been described with reference to FIGS. 3A to 3I. The first gate structure includes a gate dielectric layer 301 on the exposed surface (i.e., the surface portion above insulating region 206) of first fin 212, a first high-k dielectric layer 318 on gate dielectric layer 301, and a first gate 319 on first high-k dielectric layer 318. The second gate structure includes an interface layer 307 on the exposed surface (i.e., the surface portion above insulating region 206) of second fin 222, a second high-k dielectric layer 328 on interface layer 307, and a second gate 329 on second high-k dielectric layer 328.

Embodiments of the present disclosure also provide a semiconductor device. Referring to FIG. 2C, the semiconductor device may include a substrate 201, a plurality of fins 202, a hardmask layer 203 on fins 202, and an insulating region 205 (corresponding to the second insulting layer) on substrate 201 for isolating fins 202. In the embodiment, insulating region 205 has an upper surface that is higher than a bottom surface of hardmask layer 203, and corners and edges of the upper portion of fins having a rounded shape. In one embodiment, the distance between the upper surface of insulating region 205 and the bottom surface of hardmask layer 203 is in the range between 3 nm and 15 nm (e.g., 5 nm, 8 nm, 10 nm, or 12 nm) to prevent oxygen in a subsequent oxidation process and some other elements (e.g., hydrogen) in the environment in the annealing process to excessively enter into the fins.

Embodiments of the present disclosure further provide a second semiconductor device. Referring to FIG. 2E, the second semiconductor device may include a substrate 201, a plurality of fins 202 on substrate 201, and an insulating region 206 for isolating fins 202. Insulating layer 206 has an upper surface that is lower than an upper surface of fins 202. Corners and edges of the upper portion of fins 202 have a rounded shape. In one embodiment, fins 202 includes a first fin 212 for a first device and a second fin for a second device. In one embodiment, the first device includes an input/output device, and the second device includes a core device.

Embodiments of the present disclosure further provide a third semiconductor device. Referring to FIG. 3I, the third semiconductor device may further include a first gate structure on first fin 212 and a second gate structure on second fin 222 comparing to the second semiconductor device of FIG. 2E. In one embodiment, the first gate structure on first fin 212 includes a gate dielectric layer on the exposed surface of the first fin, a first high-k dielectric layer on the gate dielectric layer, and a first gate on the first high-k dielectric layer. The second gate structure on the second fin include an interface layer on the exposed surface of the second fin, a second high-k dielectric layer on the interface layer, and a second gate on the second high-k dielectric layer. In one embodiment, the interface layer of the second gate structure has a thickness that is smaller than the thickness of the gate dielectric layer of the first gate structure. The specific structure of the first gate structure and the second gate structure has been described in detail in above section with reference to FIGS. 3A to 3I and will not be repeated herein for the sake of brevity.

In summary, embodiments of the present disclosure provide a detailed description of a method for manufacturing a semiconductor device, and the semiconductor device fabricated using the described method. Well-known structures and processes have not been shown in detail in order not to obscure the embodiments.

It is to be understood that the above described embodiments are intended to be illustrative and not restrictive. Many embodiments will be apparent to those of skill in the art upon reviewing the above description. The scope of the invention should, therefore, be determined not with reference to the above description, but instead should be determined with reference to the appended claims along with their full scope of equivalents.

What is claimed is:

1. A method for manufacturing a semiconductor device, comprising:
providing a substrate structure including a substrate, a plurality of fins on the substrate, a hardmask layer on the fins, and a first insulating layer on the substrate for isolating the fins, the first insulating layer having an upper surface substantially flush with an upper surface of the hardmask layer;
etching back the first insulating layer to form a second insulating layer having an upper surface lower than a bottom surface of the hardmask layer;
performing an oxidation process or an annealing process on the second insulating layer;
removing the hardmask layer after performing the oxidation process or the annealing process;
etching back the second insulating layer to form an insulating region having an upper surface lower than an upper surface of the fins.

2. The method of claim 1, wherein a distance between the upper surface of the second insulating layer and the bottom surface of the hardmask layer is in a range between 3 nm and 15 nm.

3. The method of claim 1, wherein the oxidation process comprises a dry oxidation process, a wet oxidation process, or an in-situ steam generation process.

4. The method of claim 1, wherein the annealing process is performed in an annealing environment including hydrogen or helium, at a temperature in a range between 600 oC and 800 oC, at a pressure in a range between 10 Torr and 1 atmosphere, and for a time period in a range between 10 minutes and 240 minutes.

5. The method of claim 1, wherein the plurality of fins comprise a first fin for a first device and a second fin for a second device.

6. The method of claim 5, further comprising:
forming a first gate structure on the first fin and a second gate structure on the second fin;
wherein the first gate structure comprises a gate dielectric layer on an exposed surface of the first fin, a first high-k dielectric layer on the gate dielectric layer, and a first gate on the first high-k dielectric layer; and
wherein the second gate structure comprises an interface layer on an exposed surface of the second fin, a second high-k dielectric layer on the interface layer, and a second gate on the second high-k dielectric layer.

7. The method of claim 6, wherein forming the first gate structure on the first fin and the second gate structure on the second fin comprises:
forming a first dummy gate dielectric layer on the exposed surface of the first fin;
forming a second dummy gate dielectric layer on the exposed surface of the second fin, the first dummy gate dielectric layer having a thickness greater than a thickness of the second dummy gate dielectric layer;
forming dummy gates on the first dummy gate dielectric layer and on the second dummy gate dielectric layer;
forming an interlayer dielectric layer on the dummy gates;
planarizing the interlayer dielectric layer to expose a surface of the dummy gate;
removing the dummy gate;
removing the second dummy gate dielectric layer;
forming the interface layer on the exposed surface of the second fin;
forming a high-k dielectric layer on the interface layer and on the first dummy gate dielectric layer, the first dummy gate dielectric layer being a gate dielectric layer, a portion of the high-k dielectric layer on the first dummy gate dielectric layer being a first high-k dielectric layer, and a portion of the high-k dielectric layer on the interface layer being a second high-k dielectric layer; and
forming the first gate on the portion of the high-k dielectric layer on the first dummy gate dielectric layer and the second gate on the portion of the high-k dielectric layer on the interface layer.

8. The method of claim 5, wherein the first device comprises an input/output device, and the second device comprises a core device.

9. A semiconductor device, comprising:
a substrate;
a plurality of fins on the substrate and having rounded corners and edges on an upper portion of the fins;
a hardmask layer on the fins; and
an insulating region on the substrate for isolating the fins and having an upper surface higher than a bottom surface of the hardmask layer.

10. The semiconductor device of claim 9, wherein a distance between the upper surface of the insulating region and a bottom surface of the hardmask layer is in a range between 3 nm and 15 nm.

11. A semiconductor device, comprising:
a substrate;
a plurality of fins on the substrate and having rounded corners and edges on an upper portion of the fins;
a hardmask layer on the fins; and
an insulating region on the substrate for isolating the fins and having an upper surface lower than an upper surface of the fins.

12. The semiconductor device of claim 11, wherein the plurality of fins comprise a first fin for a first device and a second fin for a second device, the first fin having an exposed surface above the upper surface of the insulating region, and the second fin having an exposed surface above the upper surface of the insulating region.

13. The semiconductor device of claim 12, further comprising:
a first gate structure on the first fin and comprising:
a gate dielectric layer on the exposed surface of the first fin;
a first high-k dielectric layer on the gate dielectric layer; and
a first gate on the first high-k dielectric layer; and
a second gate structure on the second fin and comprising:
an interface layer on the exposed surface of the second fin;
a second high-k dielectric layer on the interface layer; and
a second gate on the second high-k dielectric layer.

14. The semiconductor device of claim 13, wherein the interface layer of the second gate structure has a thickness that is smaller than a thickness of the gate dielectric layer of the first gate structure.

15. The semiconductor device of claim 12, wherein the first device comprises an input/output device; and the second device comprises a core device.
